(19) United States
(12) Patent Application Publication
(10) Pub. No.: US 2010/0107285 A1
(43) Pub. Date: Apr. 29, 2010

(54) TUNABLE BIO-FUNCTIONALIZED NANOELECTROMECHANICAL SYSTEMS HAVING SUPERHYDROPHOBIC SURFACES FOR USE IN FLUIDS

(75) Inventors: Kamil L. Ekinci, Brookline, MA (US); Victor Yakhot, Newton, MA (US)

Correspondence Address: WEINGARTEN, SCHURGIN, GAGNEBIN & LEBOVICI LLP, TEN POST OFFICE SQUARE, BOSTON, MA, 02109, US

(73) Assignee: TRUSTEES OF BOSTON UNIVERSITY, Boston, MA (US)

(21) Appl. No.: 12/532,010

(22) PCT Filed: Mar. 20, 2008
(86) PCT No.: PCT/US08/03719

§ 371 Date: Sep. 18, 2009

Related U.S. Application Data
(60) Provisional application No. 60/919,122, filed on Mar. 20, 2007.

(51) Int. Cl. G01Q 30/14; B05D 5/12; B29C 43/00; G03F 7/20; G01N 29/00

(52) U.S. Cl. 850/15; 427/58; 264/319; 430/296; 430/311; 73/61.49; 73/579

(57) ABSTRACT

Tunable, bio-functionalized, nanoelectromechanical systems (Bio-NEMS), micromechanical resonators (MRs), nanomechanical resonators (NRs), surface acoustic wave resonators, and bulk acoustic wave resonators having superhydrophobic surfaces for use in aqueous biochemical solutions. The MRs, NRs or Bio-NEMS include a system resonator that can vibrate or oscillate at a relatively high frequency and to which an analyte molecule(s) contained in the solution ○ can attach or upon which small molecular-scale forces can act; a device for adjusting a relaxation time of the solution, to increase the quality (Q-factor) of the resonator inside the solution, to reduce energy dissipation into the solution; and a device for detecting a frequency shift in the resonator due to the analyte molecule(s) or applied molecular-scale forces. The resonator can include roughness elements that provide superhydrophobicity and, more particularly, gaps between adjacent asperities for repelling the aqueous solution from the surface of the device.

### CROSS REFERENCE TO RELATED APPLICATIONS

The right to priority to U.S. Provisional Patent Application No. 60/919,122 filed on Mar. 20, 2007 and entitled “NER: BIO-NEMS IN FLUID: Optimization Through Viscosity Engineering” is hereby asserted.

### STATEMENT REGARDING FEDERALLY SPONSORED RESEARCH OR DEVELOPMENT

The United States Government has a paid-up license in this invention and the right in limited circumstances to require the patent owner to license others on reasonable terms as provided for by the terms of Contract Number CMS-0324416 awarded by the National Science Foundation.

### BACKGROUND OF THE INVENTION

The present invention relates generally to tunable micromechanical resonators (MR), nanomechanical resonators (NR), surface acoustic wave resonators, and bulk acoustic wave resonators (referred to as MRs/NRs, hereafter) and, more particularly, to bio-functionalized nanoelectromechanical systems (Bio-NEMS) having super-hydrophobic surfaces for use in evaluating the nature and concentration of analytes in aqueous biochemical solutions and for measuring small interaction forces in atomic scale scanning probe microscopy.

NEMS-based sensing using a vibrating or oscillating NEMS resonator has been suggested by others. Referring to FIG. 1, resonator beams 10 can be patterned on a silicon-on-insulator (SOI) wafer, e.g., using electron beam lithography, metal deposition, lift-off techniques, and various etching techniques, and are operated in flexural modes using optical and/or capacitive techniques. By actuating the NEMS sensor 10 harmonically at or near its fundament resonant frequency, small frequency shifts can be detected with a high degree of sensitivity. Hence, as analyte molecules or a single molecule attach to the functionalized layer on the surface of the device 10, frequency shifts can be measured that provide indicia of the nature and concentration of the analyte molecules.

In this size regime, NEMS provides relatively high fundamental resonant frequencies, very small active masses, relatively low intrinsic energy dissipation, a relatively high intrinsic quality (Q-) factor, very small heat capacities, and so forth. In combination, these attributes can provide unprecedented sensitivities at relatively high operating frequencies with a potential for a wide range of sensing, actuating, and signal processing applications.

However, high-impact applications of Bio-NEMS are designed for use in an aqueous bio-chemical solution at or near ambient atmosphere. Disadvantageously, referring to FIG. 2, resonance curves for a NEMS resonator in a high vacuum 22 and at atmospheric pressure 24 are shown. FIG. 2 shows that, for a NEMS resonator in high vacuum, the Q-factor is about 1100. However, at atmospheric pressure, the Q-factor is only about 100. Moreover, the Q-factor in water is approximately 2-5, which makes resonator applications in fluids impractical.

In resonant operation, Q-factor reduction is accompanied by other undesirable consequence. First, signal size decreases with decreasing Q-factor. Subsequently, resonator sensitivity to added mass and/or force suffers. Consequently, testing at ambient temperatures and pressures using convention NEMS is difficult.

More problematically, in fluid, the resonator of the conventional Bio-NEMS loses stored energy to the fluid. Friction at the solid-fluid interface (“fluid friction”) is the main damping mechanism leading to a decrease in the Q-factor. Fluidic dissipation becomes more acute when using nanoscale resonators.

Indeed, energy loss associated with a resonator operating in a viscous fluid is well known to those of ordinary skill in the art. Macroscopic resonators such as quartz crystal microbalances and surface acoustic wave (SAW) sensors have been adapted for use in fluids. Micro-cantilevers have also been adapted for use in fluids in various applications of Atomic Force Microscopy (AFM). System-level solutions have included positive feedback, phase-locked loops, parametric amplification, and the like. However, in all of these applications of MRs/NRs, especially for Bio-NEMS, system-level approaches are extremely challenging.

Accordingly, it would be desirable to provide a MR/NR devices for use in aqueous biochemical solutions that does not suffer from the disadvantages of conventional devices. Specifically, it would be desirable to provide a sensor-level solution that minimizes energy dissipation to the fluid, i.e., reduces fluidic friction, and that optimizes the resonator signal-to-noise ratio. More specifically, it would be desirable to provide technology that increases the quality (Q-)factor of MRs/NRs when the resonator is being used in such fluids and, moreover, that is tunable as a function of the relaxation time of the fluid. It would further be desirable to provide Bio-NEMS device with such a high Q-factor that it is capable of single bio-molecular detection with a very high mass resolution.

With resonant Atomic Force Microscopy (AFM), the very same problem makes AFM imaging and force measurements in water quite challenging. For example, in AFM, a vibrating micro-cantilever can be used to detect small nanoscale forces from the surface for mapping the surface topography. However, in water, the force sensitivity, and hence, the signal-to-noise ratio decreases because the Q-factor of the cantilever decreases, e.g., to about 10.

Accordingly, a variety of advanced probe microscopy techniques, such as AFM and magnetic resonance force microscopy (MRFM), will benefit immensely from the development of micro-cantilever sensor probes with increased Q-factor for use in water.

### BRIEF SUMMARY OF THE INVENTION

Tunable, bio-functionalized, nanoelectromechanical systems (Bio-NEMS), micromechanical resonators (MR), nanomechanical resonators (NR), surface acoustic wave resonators, and bulk acoustic wave resonators for use in aqueous biochemical solutions are disclosed. The devices include a micromechanical, nanomechanical or acoustic mode resonator to which an analyte molecule(s) contained in the solution can attach; means for adjusting the relaxation time of the solution, to increase the intrinsic quality (Q-) factor of the resonator in the solution, which reduces energy dissipation into the solution; and a means for detecting a frequency shift in the resonator due to the presence of analyte molecule(s) on the resonator. Optionally, the resonator can have superhydrophobic surfaces, such as roughness elements that reduce energy dissipation in the solution.

Also disclosed is a method for increasing the intrinsic quality (Q-) factor of the resonator in the solution and for reducing energy dissipation into the solution. The method includes increasing the relaxation time of the solution by adding a polymer to the solution. Optionally, the method can further include providing a superhydrophobic surface.

### BRIEF DESCRIPTION OF THE SEVERAL VIEWS OF THE DRAWING

The invention will be more fully understood with reference to the following Detailed Description of the Invention in conjunction with the Drawings of which:

FIG. 1 shows an illustrative doubly-clamped NEMS resonator beam in accordance with the prior art;

FIG. 2 shows a resonance curve of a NEMS resonator in a high vacuum and at atmospheric pressure in accordance with the prior art;

FIG. 3 shows an oscillating, infinite plate model surrounded by a fluid medium in accordance with the prior art;

FIG. 4 shows damping factor variation with respect to relaxation time;

FIG. 5 shows Quality (Q-) factor variations with respect to pressure;

FIG. 6 shows normalized Q-factor variations with respect to frequency;

FIG. 7A shows a wetted hydrophilic surface;

FIG. 7B shows a wetted, hydrophobic surface;

FIG. 7C shows a wetted, superhydrophobic surface;

FIG. 8 shows a no slip condition for a hydrophilic or slightly hydrophobic surface;

FIG. 9 shows a slip condition for a superhydrophilic surface;

FIG. 10 shows a block diagram of a biofunctionalized NEMS in accordance with the present invention;

FIG. 11 shows an exemplary superhydrophobic surface in accordance with the present invention; and

FIG. 12 shows an exemplary superhydrophobic surface for use with a micro-cantilever in accordance with the present invention.

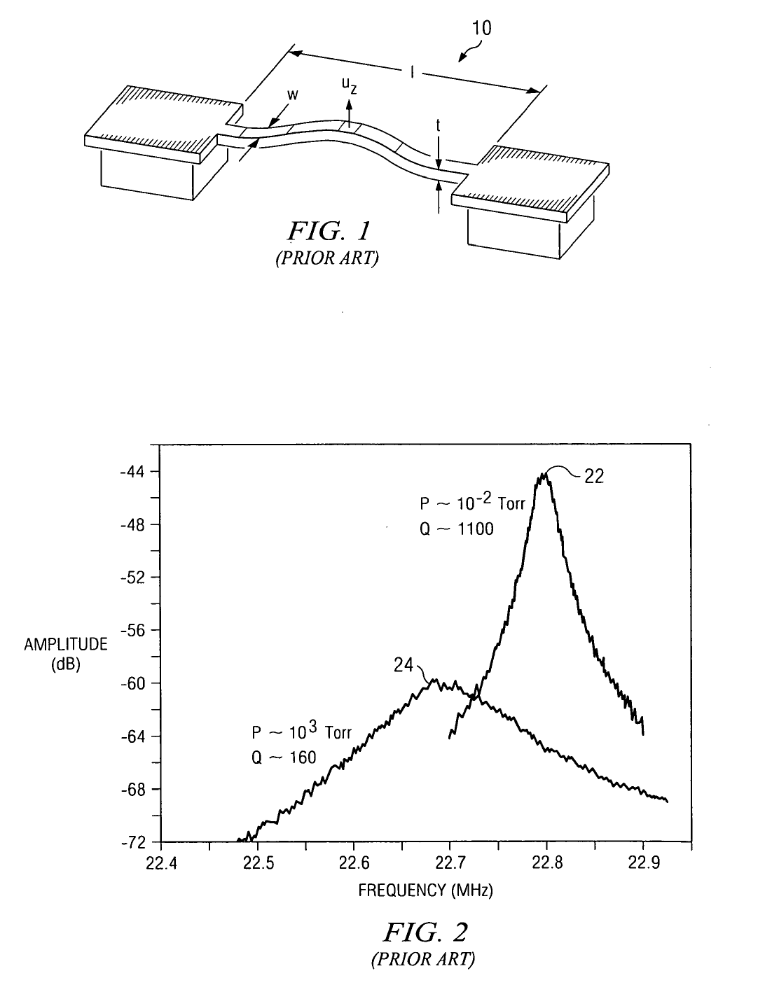

### DETAILED DESCRIPTION OF THE INVENTION

U.S. Provisional Patent Application No. 60/919,122 filed on Mar. 20, 2007 and entitled “NER: BIO-NEMS IN FLUID: Optimization Through Viscosity Engineering” is incorporated herein in its entirety.

All fluids—whether liquid, gaseous or a combination of the two—flow in distinct regimes: molecular, viscous (or laminar), and turbulent, in which flow properties are determined by length scales and by time scales.

### Theoretical Background

According to classic fluid flow theories, Newtonian fluid approximations can be used to describe macroscopic fluidic phenomena as long as the Knudsen and/or the Weissenberg numbers are very small, i.e., much less than unity (l). By definition, the Knudsen number (Kn) is a ratio of mean free path of individual molecules (λ) to the main length scale or structure size (L) in the flow, e.g., the characteristic length scale of the nano-system, or

Kn=λ/L. [EQN. 1]

When Knudsen numbers are less than unity, flow is viscous or laminar, whereas when Knudsen numbers are greater than unity, flow is molecular. Accordingly, the magnitude of the Knudsen number determines whether or not flow of the medium is a continuum.

The Weissenberg number (Wi) is defined as the ratio of the relaxation time (τ) of the fluid to the time scale (T) of the system, or

Wi=τ/T. [EQN. 2]

Classic Newtonian fluid approximations, however, are only accurate within the limitations of small Knudsen and Weissenberg numbers, which is to say when the Knudsen and Weissenberg numbers are much less than unity, i.e., Kn<<1 and Wi<<1. This, however, can be problematic with nano-systems in which Kn and Wi are not necessarily small numbers.

For example, with nano-systems, the length scale (L) of the system, which is in the denominator of EQN. 1, is typically measured in sub-microns and the time scale (T) of the system, which is in the denominator of EQN. 2, is typically measured in 10⁻⁸ to 10⁻⁹ seconds. In short, as the device size becomes smaller and smaller, the Knudsen number necessarily increases, moving away from Newtonian approximations. Furthermore, as the imposed high-frequency motion of Bio-NEMS increases, the Weissenberg number becomes larger, further moving away from Newtonian approximations.

Thus, there are several challenges associated with formulating the fluid dynamics of NEMS, Bio-NEMS, and other high-frequency MRs/NRs. Indeed, difficulties arise from the very characteristic length and time scale of these devices. As a result, one cannot apply Newtonian fluid dynamics to high frequency MRs/NRs and, in particular, to Bio-NEMS in a straightforward manner.

Notwithstanding the impact of the dimensions and operating conditions of nano-systems on the Knudsen and Weissenberg numbers, as the Weissenberg number approaches infinity, which is to say as τ/T≈ωτ→∞, the behavior of the system transitions from visco-elastic to elastic. Advantageously, as ωτ→∞ and the fluid becomes elastic, dissipation of energy to the fluid saturates and is reduced. As a result, it is possible to “tune” the viscosity of the fluid by “tuning” the relaxation time in the fluid. Advantageously, tuning the relaxation time of the fluid results in an increase in the Q-factor of MRs/NRs, and, in particular, of the Bio-NEMS in the fluid.

At the continuum extreme, the classical equations of fluid dynamics are the well-known Navier-Stokes equations, which are expressed in terms of conservation of mass and momentum. For an oscillatory problem, when there is an externally-imposed flow frequency, the Navier-Stokes equations take the non-dimensional form:

$${Re}_{ω} \frac{\partial \vec{u}}{\partial t} + {Re}_{u} ( \vec{u} \cdot \vec{∇} ) \vec{u} = - \vec{∇} p + {∇}^{2} \vec{u} , \\ \vec{∇} \cdot \vec{u} = 0 \qquad [ EQN . 3 ]$$

where Reᵤ corresponds to the velocity-based Reynolds number and Re_{ω} corresponds to the frequency-based Reynolds number. The velocity-based Reynolds number (Reᵤ) expresses the ratio between inertial forces and viscous forces, while the frequency-based Reynolds number (Re_{ω}) expresses the ratio between inertial forces and viscous forces, using the approximation:

Re_{ω}˜L²ω/υ

where υ is the viscosity of the fluid and the oscillation period, l/ω, establishes the characteristic time.

The Navier-Stokes equations have been applied to describe the oscillatory motion of AFM micro-cantilevers in liquid. Indeed, for the size and at the frequency range associated with micro-cantilevers, the Navier-Stokes solutions provide good agreement with experiments—even though these solutions may present computational challenges. However, when flow frequency becomes relatively large, the Navier-Stokes equations become inaccurate—as discussed in more detail below. In short, at relatively high frequencies, the linear relation between stress and rate-of-strain in a Newtonian fluid breaks down.

At the opposite extreme, for very long mean free path, instead of a continuum, one goes into collisionless or free molecular flow. Very few practical cases of interest, however, can be described without taking into consideration the effects of collisions.

When collisions predominate, but continuum is not yet reached, the fluidic regime is known as the transition regime. In contrast to the continuum limit, obtaining a solution in the transition regime is not trivial, as one needs to solve the Boltzmann equation.

The Boltzmann equation for the distribution function, ƒ, states that changes in ƒ in seven-dimensional phase-space are due to the motion of the particles and to collisions. This is usually expressed as:

$$\frac{\partial f}{\partial t} + \vec{u} \cdot \vec{∇} f = {( \frac{δ f}{δ t} )}_{collisions} \qquad [ EQN . 4 ]$$

However, in a relaxation time approach, the relaxation term to equilibrium distribution, ƒ_{eq} replaces the collision term as follows:

$$\frac{δ f}{δ t} + \vec{u} \cdot \vec{∇} f = \frac{f - {f}_{eq}}{τ} , \qquad [ EQN . 5 ]$$

where τ is the relaxation time. This forms the basis of the present invention to describe the fluidics of a micromechanical and/or nanomechanical resonator (MR/NR).

More specifically, for liquid flow generated by an infinite Stokes plate in a fluid that is oscillating at a frequency ω, the Chapmnan-Enskog expansion of the Boltzmann-BKG equation can be expressed in terms of two dimensionless parameters: one based on length scales, i.e., the Knudsen number, and one based on time scales, i.e., the Weissenberg number. Where δ is a boundary layer thickness, Kn=λ/L=λ/δ and where u is the boundary layer velocity,

$$Wi = \frac{τ}{u} \frac{δ u}{δ t} \qquad [ EQN . 6 ]$$

According to the plate problem above, as the frequency of oscillation increases, ω→∞, Kn→0 and Wi→∞. Moreover, although with standard kinetic theory of gases, Kn and Wi are coupled and related to the point of being surrogates one for the other, with increasing frequency, an externally imposed time scale placed on the resonator approximately equal to 1/ω, decouples the numbers.

With this decoupling, a closed-form solution can be obtained for the entire (dimensionless) frequency range between 0≦ωτ<∞ using EQN. 5, to describe non-Newtonian fluid behavior at high frequencies by accounting for the relaxation time, τ, of the fluid. Dissipation, γ, over the entire frequency range is given by the expression:

$$γ = \frac{2 p \sqrt{ω v}}{{p}_{s} {h ( 1 + {ω}^{2} {τ}^{2} )}^{3 / 4}} [ \begin{matrix}( 1 + ω τ ) cos ( \frac{{tan}^{- 1} ω τ}{2} ) - \\ ( 1 - ω τ ) sin ( \frac{{tan}^{- 1} ω τ}{2} )\end{matrix} ] . \qquad [ EQN . 7 ]$$

Thus, the dissipation behavior of the fluid for oscillations at high and at low frequencies can be different. Moreover, in the hydrodynamic, low frequency limit where ωτ→0, EQN. 7 reduces to:

$$γ = \frac{\sqrt{pv ω / 2}}{{p}_{s} h} ∝ \sqrt{ω \cdot b} \qquad [ EQN . 8 ]$$

Whereas, in the kinematic, high frequency limit where ωτ→∞, EQN. 7 reduces to:

$$γ = \frac{2 p ω τ \sqrt{ω v}}{{p}_{s} {h ( 1 + {ω}^{2} {τ}^{2} )}^{3 / 4}} ∝ {ω}^{0} . \qquad [ EQN . 9 ]$$

Thus, effective viscosity of the Newtonian fluid decreases with increasing relaxation time, which is to say that an increase in relaxation time results in a reduction of the apparent viscosity at high frequencies due to the saturation behavior of the fluid at higher frequencies.

### Nano-fluidics and Micromechanical and Nanomechanical Resonators

In order to describe the fluidics of a micromechanical resonator (MR) or a nanomechanical resonator (NR), the Boltzmann equation is used to describe oscillating flow using the relaxation time approximation. The Boltzmann-based theory suggests that the result is independent of the nature of the fluid and, furthermore, that energy dissipation saturates as ωτ→∞. Accordingly, a solution for a plate, oscillating at a frequency, ω, in a fluid medium, having a relaxation time, τ, can be obtained for the entire dimensionless frequency range of 0≦ωτ≦∞. Advantageously, high-frequency MRs/NRs, therefore, have the potential to achieve relatively high Q-factors when they are surrounded by gaseous environments.

Indeed, the relaxation time approach of the Boltzmann equation indicates that, although energy dissipation into a fluid having a relatively low Weissenberg number limit is governed by visco-elastic dynamics and the Navier-Stokes relationships, at higher frequencies, in a strongly non-Newtonian interval, in which Wi>1, the dominant energy dissipation mechanism becomes radiation of undamped, transverse elastic waves.

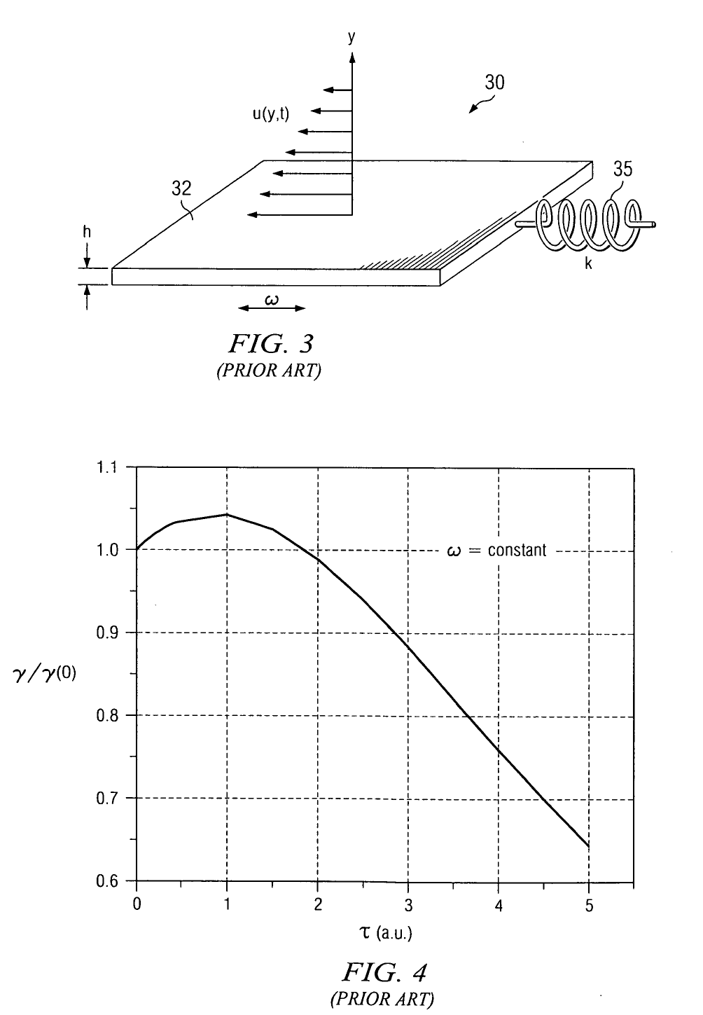

A simple plane resonator, or plate, model is shown in FIG. 3. An oscillating, infinite plate 30 of thickness, h, is surrounded by a fluid medium. A mass-less spring 35 having a spring stiffness constant, k, is attached to the plate 30 so that the plate 30 dissipates energy into the fluid through friction. The force R(t) driving the plate 30 obeys the damped, harmonic equation R(t)=x″+γx′+kx, where the damping constant, γ, gives rise to the friction force:

γx′=γu(0,t),

which is to say, that the friction force acting per unit mass of the plate surface 32, γx, can be found using fluid velocity solutions on the plate surface 32, u(0,t).

Damping factor variation with respect to relaxation time, τ, at a given, constant frequency is shown graphically in FIG. 4. Referring to the curve, in the Newtonian interval ωτ<1, a mild initial increase in Q-factor occurs. However, as relaxation time increases and as ωτ→∞, the damping factor, which is to say, the effective viscosity of the fluid acting on the plate 30, decreases well below the Newtonian magnitude, thereby reducing energy dissipation to the fluid. In short, at higher frequencies, energy loss to the surrounding fluid can be reduced significantly. Hence, relaxation time can be manipulated, resulting in a reduction of the effective viscosity of the fluid.

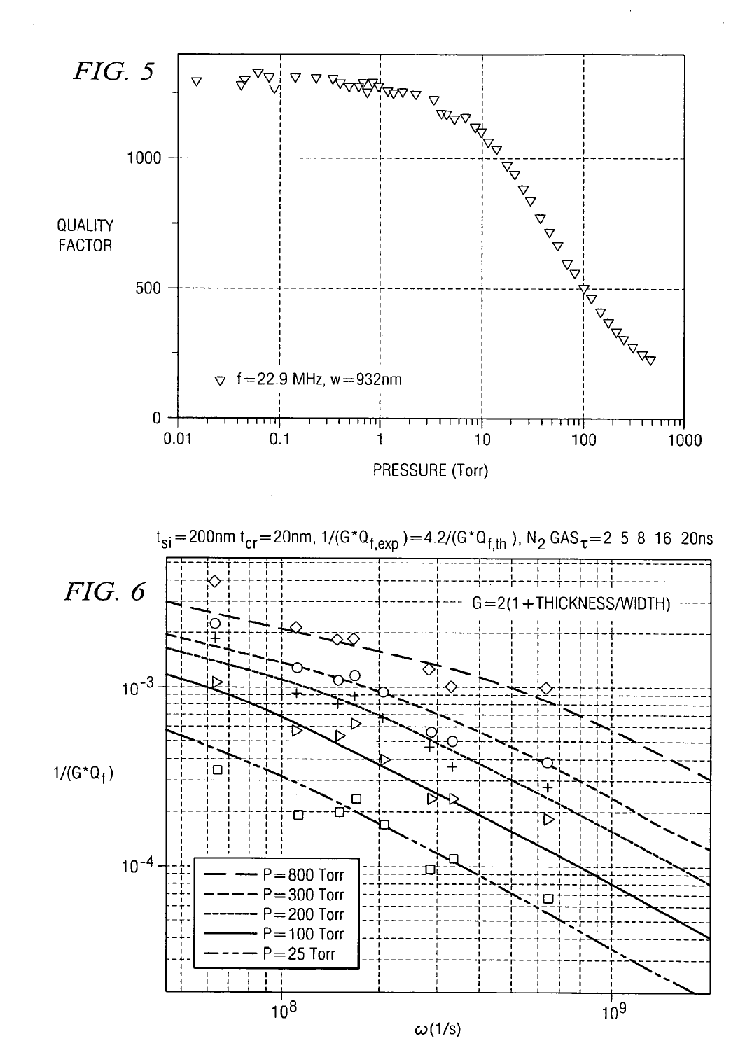

Through experimentation, in a rarefied gas environment, where one can “tune” pressure, p, and relaxation time, τ, the relationships between the Q-factor, i.e., energy dissipation, and pressure and between a geometrically-normalized Q-factor and frequency are shown in FIG. 5 and FIG. 6, respectively. Normalization of the Q-factor in connection with FIG. 6 accounts for the geometrical effects due to the finite size of the experimental device with respect to the assumed “infinite” plate.

Relaxation time is understood to be the time it takes a fluid after a perturbation, to return to its bulk equilibrium configuration. However, in order to evaluate the impact of pressure on relaxation time for MRs/NRs at higher frequencies, because the infinite plate is oscillating so rapidly, it is not possible to reach equilibrium of the bulk fluid. This suggests that a local equilibrium characterized by a different time scale must exist. Through experimentation and comparison of Q-factor results with theoretical Q-factor estimates and based on the kinetic theory of gases, the relationship between pressure and relaxation time is given by the equation:

τ=1600/p [EQN. 5]

where p is measured in Torr units and τ is measured in nanoseconds.

In FIG. 5, one observes that intrinsic energy (Q-factor) dissipation predominates at relatively low pressures, e.g., less than 1 Torr, but at higher pressures, fluidic effects exert a greater influence over energy dissipation. In FIG. 6 theoretical predictions and Q-factor measurements validate the pressure/relaxation time tuning approach.

In liquids, and, more particularly, in aqueous solutions, e.g., water, relaxation time tuning can be accomplished using well-known, straightforward approaches, such as by mixing or by dissolving a relatively high molecular mass polymer in the aqueous solution, to increase relaxation time. Slow-moving macromolecules of the polymer affect the global relaxation time of the aqueous solution. The higher the molecular weight, the larger the relaxation time of the polymeric solution.

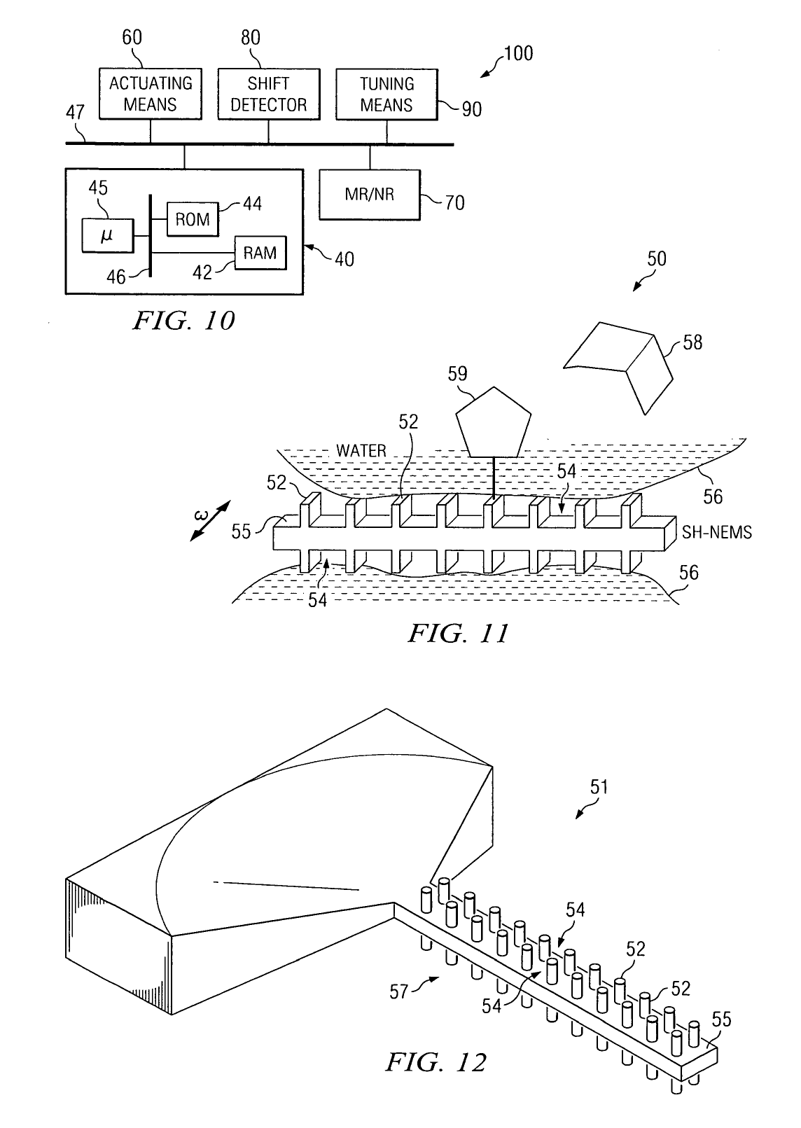

Accordingly, referring to FIG. 10, a tunable, biofunctionalized electromechanical system 100 for use in an aqueous biochemical solution according to the present invention is shown. The system 100 includes a system resonator 70, means for actuating the resonator 60, means for detecting a frequency shift 80, means for adjusting a relaxation time of the solution 90, and a controller 40.

The system resonator 70 can be a micromechanical resonator (MR) or a nanomechanical resonator (NR), which can include NEMS, Bio-NEMS, and microelectromechanical systems (MEMS) resonators as well as surface acoustic wave and bulk resonators. For example, the structure of the MR/NR 70 can include a doubly-clamped beam, a cantilevered beam, a tuning fork, a micro-cantilever (for AFM application), and the like. An enclosure 71 allows the atmospheric conditions used in practicing the invention. Environmental controls 73 may be provided to achieve this. The MR/NR 70 is structured and arranged to include a functionalized surface to which at least one analyte molecule contained in the aqueous biochemical solution can attach or can be attached. The MR/NR 70 is adapted to vibrate or oscillate at relatively high frequencies.

Means for actuating the resonator 60 and for detecting a frequency shift 80 from the fundamental response frequency of the resonator 70 are well-known to the art and will not be described in detail herein. The motion and frequency-shift detecting means can include optical, piezoresistive, piezoelectric, and capacitive means and the like.

The means for adjusting the relaxation time 90 of the solution is adapted to reduce the amount of energy dissipation into the solution and, more particularly, to reduce the effective viscosity of the solution. Other means of adjusting the relaxation time 90 can include means for adding a predetermined amount of a benign polymer to a volume of the aqueous solution. Polymers, when added in relatively small quantities, increase relaxation time because the slow-moving macro-molecule of the polymer affects global relaxation time of the fluid. The higher the molecular weight, the greater the relaxation time of the solution.

Although the above descriptions deal primarily with resonators and systems 20 in which analyte molecules attach to the resonator, those skilled in the art can appreciate the applicability of the invention to tunable resonator systems for improved detection and imaging of atomic force microscopy (AFM) or magnetic resonance force microscopy (MRFM) inside an aqueous solution. The systems for AFM and MRFM use would include a system resonator, e.g., a cantilever, micro-cantilever, nano-cantilever, and the like, that is subject to the action of molecular-scale forces, which produce resonant frequency shifts as well as means for detecting the resonant frequency shifts due to the molecular-scale forces and means for adjusting the relaxation time of the solution to increase a quality (Q-) factor of the resonator and to reduce energy dissipation into said solution.

### Superhydrophobic Surfaces

As described above, one remedy of the deleterious effects of fluidic friction, is the reduction or “tuning” of the relaxation time of the fluid. Alternatively, the area of the solid-liquid interface through which fluidic friction between the fluid medium and the system is transferred can be minimized. More particularly, interfacial area reduction can be achieved using superhydrophobic surfaces. A superhydrophobic surface differs from hydrophilic and hydrophobic surfaces in that it includes random roughness elements which form a series of peaks (asperities) and valleys (gaps), which are designed to reduce surface tension.

Moreover, the superhydrophobic peaks and valleys and further hydrophobicity serve to repel the aqueous solution from the air- or gas-filled valleys, creating a negligibly small solution-device contact area. As a result, although the resonator is operating in an aqueous solution, it acts as if it were operating in a gaseous environment, in which medium very small viscous dissipation occurs.

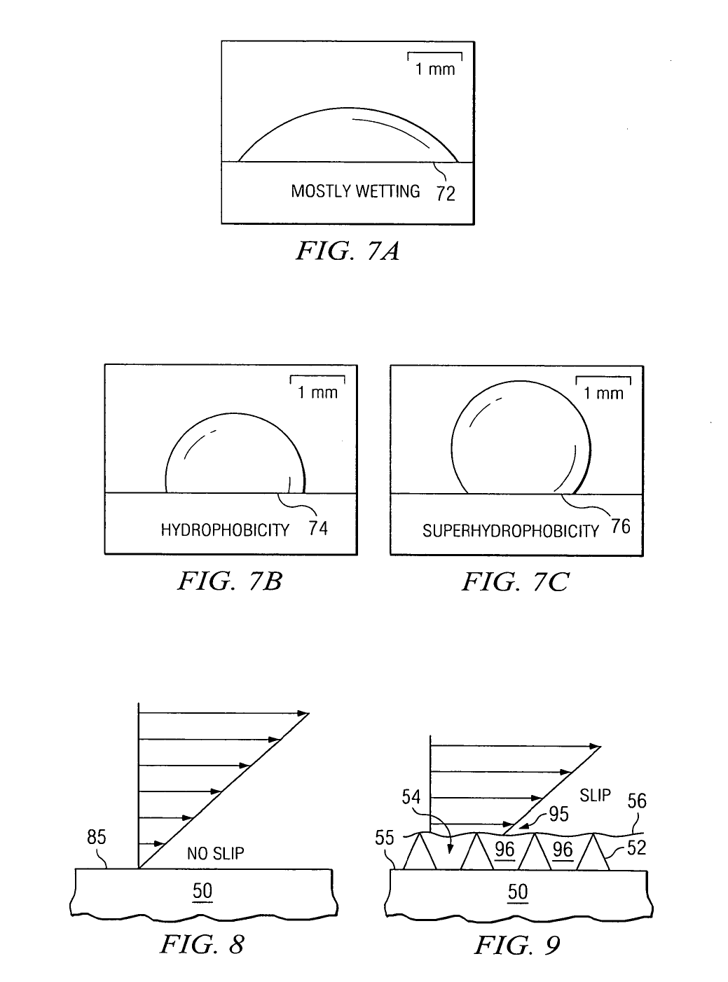

FIG. 7A depicts a hydrophilic surface that is mostly wetted. The interfacial area is shown as reference number 72. FIG. 7B depicts a fluid on a surface with hydrophobicity. The interfacial area is shown as reference number 74. FIG. 7C depicts a fluid on a surface having superhydrophobicity. The interfacial area is shown as reference number 76. By visually comparing reference numbers 72, 74, and 76, the dramatic reduction in the surface area in contact with the aqueous solution resulting from a superhydrophobic surface is demonstrated.

Exemplary superhydrophobic devices 50 are shown in FIG. 11 and FIG. 12. FIG. 11 shows a device 50 that can be doubly-clamped, cantilevered, and the like. FIG. 12 shows a micro-cantilevered embodiment 51.

The silicon devices 50 and 51 are structured and arranged to include a hydrophobic surficial layer 55 along with superhydrophobic roughness elements 52. Functional groups 59, such as labels, receptors, and the like, can be attached to or near the free ends of the roughness elements 52 to attach to analyte molecules 58 within the aqueous solution. Suitable coating materials for providing superhydrophobicity can include nanoparticles, such as carbon nanotubes, nanobricks, or nanoturf.

The roughness elements 52 can be applied to the hydrophobic surface layer 55, for example, using electron beam lithography techniques, allowing the roughness elements 52 to be defined during fabrication of the NEMS device 50. The advantage of this approach is the selectability of the asperity 52 and gap 54 parameters, e.g., period, shape, amplitude, and so forth.

Soft lithography techniques can provide scaleable manufacturing of superhydrophobic features 52. The superhydrophobic roughness elements 52 can also be manufactured in self-assembled mono-layers, in which the NEMS device 50 or 51 is first manufactured before a “wet” coating is added to the device 50. For example, depositing soot on a glass substrate produces a superhydrophobic surface.

Superhydrophobic coatings can be deposited using a solution or a spray. Deposition of a film under tension also can result in a rough surface. Annealing and heat treatment, e.g., using a laser spot beam, can generate a highly controllable roughness pattern at precise locations on the device 50 Or 51 by cutting into or melting portions of the device 50 or 51 using high temperatures.

The roughness elements 52 comprise a multiplicity of peaks and valleys, in which the asperities (peaks) are separated by gaps 54 (valleys). Due to surface tension, dissolved gas fills the gaps 54 between adjacent roughness elements 52. As a result, the liquid interface 56 remains suspended above the solid surface of the device 50.

The amplitude of the peaks and the gap spacing can be tailored to satisfy the particular application. For example, in connection with atomic force microscopy (AFM), the cantilever portion 57 (FIG. 12) can include a length and width of approximately 100 μm and 50 μm, respectively, and a thickness of approximately 500 nm. The roughness elements 52 can be, e.g., carbon nanotubes with asperities approximately 1 μm in height that are spaced approximately 1 to 10 μm apart. Alternatively, nano-bricks having an area of approximately 40 μm² and a height of approximately 1 μm can be used. Nano-turf having a post height of approximately 1 micron and a spacing of approximately 1 micron can also be used for the roughness elements 52.

The benefits of suspending the liquid interface 56 above the surface of the device 50 are shown comparatively in FIG. 8 and FIG. 9. In FIG. 8, non-slippage shear distribution of the fluid on a hydrophilic or slightly hydrophobic surface 85 is shown. In contrast, in FIG. 9, the shear stress associated with the suspended liquid interface 56 and the superhydrophobic roughness elements 52 at the surface 55 of the device 50 is essentially zero.

Surface tension within the valley gaps 54 traps air or gas 96, filling the gaps 54 and repelling the aqueous solution not only from the surface 55 of the device 50 but also from the roughness elements 52. As a result, the liquid interface 56 contacts the gas or air rather than the surface 55 of the device 50 or the roughness elements 52. Thus, the liquid interface 56 “sees” a gas and not a solid, which creates very small viscous dissipation.

Small viscous dissipation produces a significant decrease in pressure, which, advantageously, sustains the mass flux. Gas friction can be further reduced by operating the device 50 or 51 at higher frequencies and/or by adjusting the relaxation times.

As shown in FIG. 10, the system 100 is controlled by a controller 40. The controller can include a processor or micro-processor 45 that includes volatile and non-volatile memory, such as random access memory (RAM) 42 and read-only memory (ROM) 44, respectively. The ROM 44 can include applications, driver programs, look-up tables, and the like that are executable by the processing unit 45 in conformity with the steps and equations noted above. The RAM 42 can include adequate space for running or executing any of the applications, driver programs, and the like from the ROM 42. Separate buses 46 and 47 for electrically coupling the components of the controller 40 and the components of the system 100, respectively are, shown in FIG. 12. However, those skilled in the art can appreciate that all of the components described above can be coupled to a single bus.

Those of ordinary skill in the art will appreciate that variations to and modification of the above-described device, system, and method. Accordingly, the invention should not be viewed as limited except as by the scope and spirit of the appended Claims.

What is claimed is:

1. A system for use as one of a tunable, bio-functionalized a micromechanical resonator, nanomechanical resonator, NEMS resonator, microelectromechanical system resonator, Bio-NEMS resonator, surface acoustic wave resonator, and a bulk resonator for use in an aqueous biochemical solution, the system comprising:
a system resonator to which at least one analyte molecule contained in the solution can be attached; and
means for adjusting a relaxation time of the solution to reduce energy dissipation into and to reduce the relaxation time and an effective viscosity of said solution.

2. The system as recited in claim 1, wherein the resonator includes a hydrophobic layer on its surface or the surface is adapted to be superhydrophobic, to reduce surface area in contact with the solution.

3. The system as recited in claim 2, wherein the resonator further includes a plurality of roughness elements providing gaps between adjacent asperities, and wherein dissolved gas fills all or some portion of the gaps.

4. The system as recited in claim 1, further comprising means for detecting a frequency shift in the resonator due to said analyte molecule.

5. The system as recited in claim 1, wherein the system resonator is selected from the group consisting of a micromechanical resonator, a nanomechanical resonator, a NEMS resonator, a microelectromechanical system resonator, a Bio-NEMS resonator, a surface acoustic wave resonator, a bulk resonator, a doubly-clamped beam, a cantilevered beam, a tuning fork, or a micro-cantilever, which are adapted to vibrate or oscillate at relatively high frequencies.

6. A method of tuning at least one of a bio-functionalized nanoelectromechanical system (Bio-NEMS), a micromechanical resonators (MR), a nanomechanical resonator (NR), a surface wave acoustic wave resonator, and a bulk acoustic wave resonator, to increase its quality (Q-)factor, or to decrease energy dissipation in an aqueous biochemical solution, the method comprising:
attaching at least one analyte molecule contained in the solution to a system resonator;
actuating the resonator at or near the fundamental response frequency of said resonator; and
adjusting a relaxation time of the solution to reduce energy dissipation into said solution.

7. The method as recited in claim 6, wherein adjusting the relaxation time of the solution includes adding, mixing or dissolving a relatively high molecular mass polymer in the solution.

8. The method as recited in claim 6, wherein the method further includes applying a superhydrophobic layer on the resonator, to decrease an interfacial area between the aqueous solution and the resonator.

9. The method as recited in claim 6, wherein the method further includes providing a plurality of roughness elements by forming a plurality of asperities and a plurality of corresponding gaps between adjacent asperities on the resonator.

10. The method as recited in claim 9, wherein said roughness elements, asperities, and gaps are selected from the group comprising:
electron beam lithography,
soft lithography techniques,
wet coating a self-assembled mono-layer using a spray or a solution,
deposition of a film under tension,
annealing, and
heat treatment.

11. The method as recited in claim 9, the method further comprises filling all or some portion of the gaps with dissolved gas, to repel the aqueous solution from a surface of the device.

12. A kit for analyzing presence, nature, and concentration of an analyte in solution, the kit comprising:
an aqueous biochemical solution;
a system resonator to which at least one analyte molecule contained in the solution can be attached; and
means for adjusting a relaxation time of the solution to reduce energy dissipation into and to reduce the relaxation time and an effective viscosity of said solution.

13. The kit as recited in claim 12, wherein the system resonator is selected from the group consisting of a micromechanical resonator, a nanomechanical resonator, a NEMS resonator, a microelectromechanical system resonator, a Bio-NEMS resonator, a surface acoustic wave resonator, a bulk resonator, a doubly-clamped beam, a cantilevered beam, a tuning fork, or a micro-cantilever, which are adapted to vibrate or oscillate at relatively high frequencies.

14. A tunable, bio-functionalized system for use in an aqueous biochemical solution, the system comprising:
a system resonator having a hydrophobic layer on its surface and a plurality of superhydrophobic roughness elements providing gaps between adjacent asperities, to which at least one analyte molecule contained in the solution can be attached; and
means for adjusting a relaxation time of the solution to reduce energy dissipation into and to reduce an effective viscosity of said solution.

15. The system as recited in claim 14, wherein the system resonator is selected from the group consisting of a micromechanical resonator, a nanomechanical resonator, a NEMS resonator, a microelectromechanical system resonator, a Bio-NEMS resonator, a surface acoustic wave resonator, a bulk resonator, a doubly-clamped beam, a cantilevered beam, a tuning fork, or a micro-cantilever, which are adapted to vibrate or oscillate at relatively high frequencies.

16. The system as recited in claim 14, further comprising means for detecting a frequency shift in the resonator due to said analyte molecule.

17. A tunable, bio-functionalized system for use in increasing a quality (Q-)factor of an aqueous biochemical solution, the system comprising:
a system resonator to which at least one analyte molecule contained in the solution can be attached; and
means for adjusting a relaxation time of the solution to reduce energy dissipation into and to reduce an effective viscosity of said solution.

18. The system as recited in claim 17, wherein the system resonator is selected from the group consisting of a micromechanical resonator, a nanomechanical resonator, a NEMS resonator, a microelectromechanical system resonator, a Bio-NEMS resonator, a surface acoustic wave resonator, a bulk resonator, a doubly-clamped beam, a cantilevered beam, a tuning fork, or a micro-cantilever, which are adapted to vibrate or oscillate at relatively high frequencies.

19. The system as recited in claim 18, further comprising means for detecting a frequency shift in the resonator due to said analyte molecule.

20. A tunable resonator system for improved detection and imaging of atomic force microscopy (AFM) or magnetic resonance force microscopy (MRFM) inside an aqueous solution, the system comprising:
a system resonator upon which molecular-scale forces can act to produce resonant frequency shifts;
means for detecting said resonant frequency shifts using said molecular-scale forces; and
means for adjusting a relaxation time of the solution to increase a quality (Q-) factor of the resonator and to reduce energy dissipation into said solution.

21. The system as recited in claim 20, wherein the system resonator is a cantilever, micro-cantilever, or nano-cantilever.

22. The system as recited in claim 20, wherein the resonator includes a superhydrophobic surface, to decrease an interfacial area between the aqueous solution and the resonator surface.

23. The system as recited in claim 22, wherein the superhydrophobic surface includes a plurality of roughness elements that includes a plurality of asperities and a plurality of corresponding gaps between adjacent asperities on the resonator.
